(19) United States
(12) Patent Application Publication
(10) Pub. No.: US 2011/0079421 A1
(43) Pub. Date: Apr. 7, 2011

(54) PRINTED CIRCUIT BOARD AND METHOD OF MANUFACTURING THE SAME

(76) Inventors: Young Gwan KO, Gyunggi-do (KR); Ryoichi Watanabe, Gyunggi-do (KR); Sang Soo Lee, Seoul (KR); Se Won Park, Seoul (KR)

(21) Appl. No.: 12/634,520

(22) Filed: Dec. 9, 2009

(30) Foreign Application Priority Data
Oct. 6, 2009 (KR) 10-2009-0094729

(51) Int. Cl. H05K 1/11; B05D 5/12; C25D 5/00; C23F 1/00

(52) U.S. Cl. 174/262; 427/96.9; 205/187; 216/13; 216/17

(57) ABSTRACT

Disclosed herein is a printed circuit board, including: a base substrate; insulation layers which are formed on both sides of the base substrate and in which trenches are formed; and circuit layers including circuit patterns and vias formed in the trenches using a plating process. The printed circuit board is advantageous in that trenches are formed in both sides of a base substrate, so that a fine circuit pattern can be simultaneously formed on both sides thereof, thereby simplifying the manufacturing process thereof.

### CROSS REFERENCE TO RELATED APPLICATION

This application claims the benefit of Korean Patent Application No. 10-2009-0094729, filed Oct. 6, 2009, entitled “A printed circuit board and a method of manufacturing the same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, technologies for directly mounting a semiconductor chip in a printed circuit board are increasingly being required in order to keep up with the densification of semiconductor chips and the acceleration of signal transfer speed. Therefore, it is required to develop a high-density and highly-reliable printed circuit board which can keep pace with the densification of a semiconductor chip.

Required specifications of high-density and highly-reliable printed circuit boards are closely related to those of semiconductor chips. Examples of the required specifications thereof may include miniaturization of circuits, improvement of electrical properties, high-speed signal transfer, high reliability, high functionality, and the like. That is, printed circuit board manufacturing technologies which can form fine circuit patterns and micro viaholes are required in accordance with such required specifications.

Generally, examples of methods of forming a circuit pattern of a printed circuit board include a subtractive process, a full additive process, a semi-additive process and the like. Among these processes, currently, a semi-additive process which can miniaturize a circuit pattern is attracting considerable attention.

FIGS. 1 to 6 are sectional views showing a conventional method of forming a circuit pattern using a semi-additive process. The method of forming a circuit pattern is described as follows with reference to FIGS. 1 to 6.

First, as shown in FIG. 1, a viahole 16 is formed in an insulation layer 12 formed on a metal layer 14.

Subsequently, as shown in FIG. 2, an electroless plating layer 18 is formed on the inner wall of the viahole 16 and the surface of the insulation layer 12. In this case, the electroless plating layer 18 serves as a pretreatment process of subsequent processes, and the electroless plating layer 18 must have a predetermined thickness or more (for example, 1 μm or more) in order to form an electrolytic plating layer 24.

Subsequently, as shown in FIG. 3, a dry film 20 is formed on the electroless plating layer 18, and is then patterned to have an opening 22 for exposing a circuit pattern forming region.

Subsequently, as shown in FIG. 4, an electrolytic plating layer 24 is formed in the viahole 16 and the opening 22.

Subsequently, as shown in FIG. 5, the dry film 20 is removed.

Finally, as shown in FIG. 6, a part of the electroless plating layer 18, on which the electrolytic plating layer 24 is not formed, is removed using flash etching or quick etching to form a circuit pattern 28 including a via 26.

The circuit pattern 28 formed using this conventional semi-additive process is problematic in that it is easily separated from the insulation layer because it is formed on the insulation layer 12 in an embossed pattern. In particular, this semi-additive process is problematic in that it is not suitable to form a fine circuit pattern because of an undercut phenomenon occurring in the lower end of the circuit pattern 28 during flash etching or quick etching for removing the electroless plating layer 18.

Further, conventional circuit pattern forming methods are problematic in that the efficiency of the manufacturing of a multilayered printed circuit board is decreased because a circuit pattern is formed on only one side of the printed circuit board.

### SUMMARY OF THE INVENTION

Accordingly, the present invention has been made to solve the above-mentioned problems, and the present invention provides a printed circuit board which can simplify a manufacturing process and reduce manufacturing cost by forming circuit layers on both sides of a base substrate by employing trenches on both sides thereof or by simultaneously forming circuit layers on both sides thereof by employing trenches on one side thereof and using a subtractive or semi-additive process on the other side thereof, and a method of manufacturing the same.

An aspect of the present invention provides a printed circuit board, including: a base substrate; insulation layers which are formed on both sides of the base substrate and in which trenches are formed; and circuit layers including circuit patterns and vias formed in the trenches using a plating process.

Here, protrusions may be formed in the trenches.

Another aspect of the present invention provides a printed circuit board, including: a base substrate; a first insulation layer which is formed on one side of the base substrate and in which trenches are formed; a second insulation layer which is formed on the other side of the base substrate and in which viaholes are formed; a first circuit layer including circuit patterns and vias formed in the trenches formed in the first insulation layer using a plating process; and a second circuit layer including vias formed in the second insulation layer.

Here, protrusions may be formed in the trenches.

Still another aspect of the present invention provides a method of manufacturing a printed circuit board, including: forming insulation layers on both sides of a base substrate; forming trenches in the insulation layers; forming plating layers on the insulation layers including the trenches by a plating process; and forming circuit layers by removing the plating layers excessively formed on the insulating layers.

Here, in the forming of the plating layers, the plating layers may be formed by forming electroless plating layers on the insulation layers including the trenches and then electrolytic-plating the electroless plating layers.

Further, in the forming of the circuit layers, the circuit layers may be formed by etching the excessively formed plating layers.

Further, in the forming of the circuit layers, the circuit layers may be formed by grinding the excessively formed plating layers.

Still another aspect of the present invention provides a method of manufacturing a printed circuit board, including: forming a first insulation layer on one side of a base substrate, and forming a second insulation layer on the other side of the base substrate; forming trenches in the first insulation layer, and forming viaholes in the second insulation layer; and forming a first circuit layer in the trenches formed in the first insulation layer by a plating process, and forming a second circuit layer including vias on the second insulation layer by a plating process.

Here, the forming of the first circuit layer and the second circuit layer may include: forming an electroless plating layer on the first insulation layer including the trenches and then electrolytic-plating the electroless plating layer to form a first plating layer, and forming an electroless plating layer on the second insulation layer including the vias and then electrolytic-plating the electroless plating layer to form a second plating layer; removing the first plating layer excessively formed on the first insulation layer to form the first circuit layer; applying a etching resist onto the second plating layer and then forming openings for forming a circuit in the etching resist; and removing the second plating layer exposed through the openings for forming a circuit by etching and then removing the etching resist to form the second circuit layer.

Further, in the forming of the first plating layer and the second plating layer, the thickness of the first plating layer may be different from that of the second plating layer.

Further, in the forming of the first circuit layer, the first plating layer excessively formed on the first insulation layer may be removed by etching.

Further, in the forming of the first circuit layer, when the first plating layer is removed by etching, the second plating layer may be removed to a predetermined thickness by etching.

Further, in the forming of the first circuit layer, the first plating layer excessively formed on the first insulation layer may be removed by grinding.

Further, the forming of the first circuit layer and the second circuit layer may include: forming an electroless plating layer on the first insulation layer including the trenches, and forming an electroless plating layer on the second insulation layer including the vias, and then applying a plating resist on the second insulation layer and then forming openings for forming a circuit in the plating resist; electrolytic-plating the electroless plating layer to form a first plating layer on the first insulation layer including the trenches and to form a second plating layer in the openings for a circuit; removing the first plating layer excessively formed on the first insulation layer to form the first circuit layer; and stripping the plating resist and then removing the electroless plating layer to form the second circuit layer.

Further, in the forming of the first plating layer and the second plating layer, the thickness of the first plating layer may be different from that of the second plating layer.

Further, in the forming of the first circuit layer, the first plating layer excessively formed on the first insulation layer may be removed by etching.

Further, in the forming of the first circuit layer, when the first plating layer is removed by etching, the second plating layer may be removed to a predetermined thickness by etching.

Further, in the forming of the first circuit layer, the first plating layer excessively formed on the first insulation layer may be removed by grinding.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 6 are sectional views showing a conventional method of forming a circuit pattern using a semi-additive process;

FIG. 7 is a sectional view showing a printed circuit board according to a first embodiment of the present invention;

FIG. 8 is a sectional view showing a printed circuit board according to a second embodiment of the present invention;

FIGS. 9 to 12 are sectional views showing a method of manufacturing the printed circuit board according to the first embodiment of the present invention;

FIGS. 13 to 19 are sectional views showing a method of manufacturing the printed circuit board according to the second embodiment of the present invention; and

FIGS. 20 to 27 are sectional views showing a method of manufacturing the printed circuit board according to the third embodiment of the present invention.

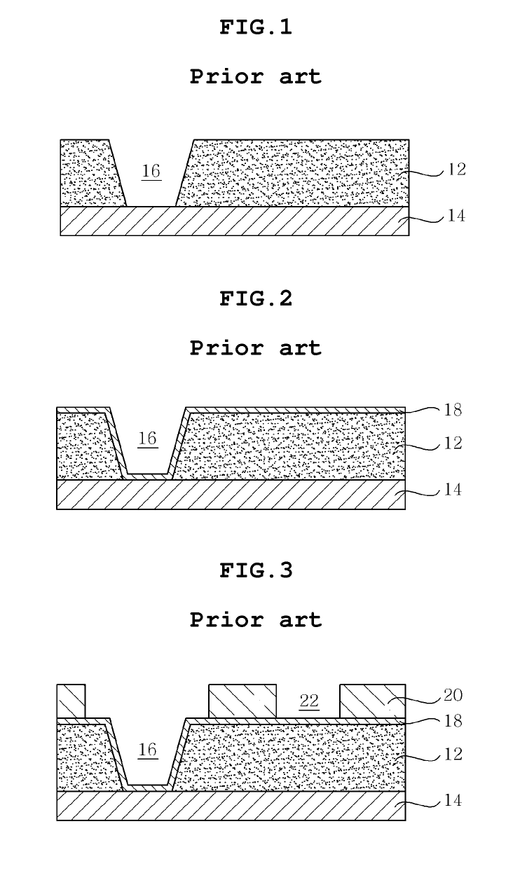

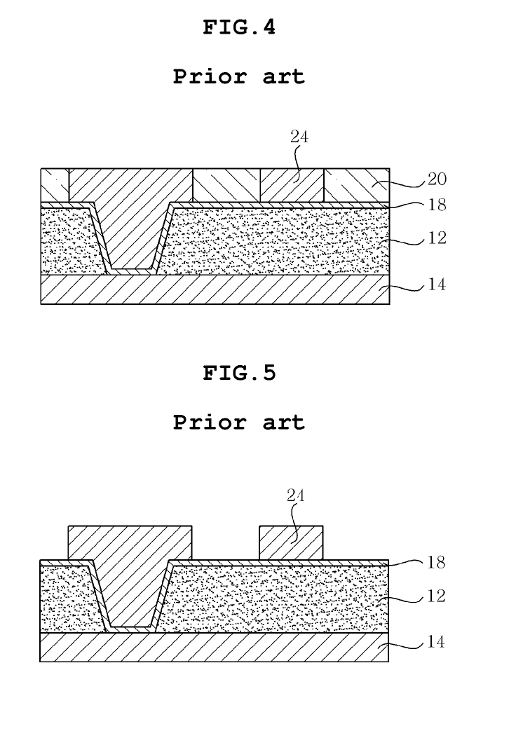

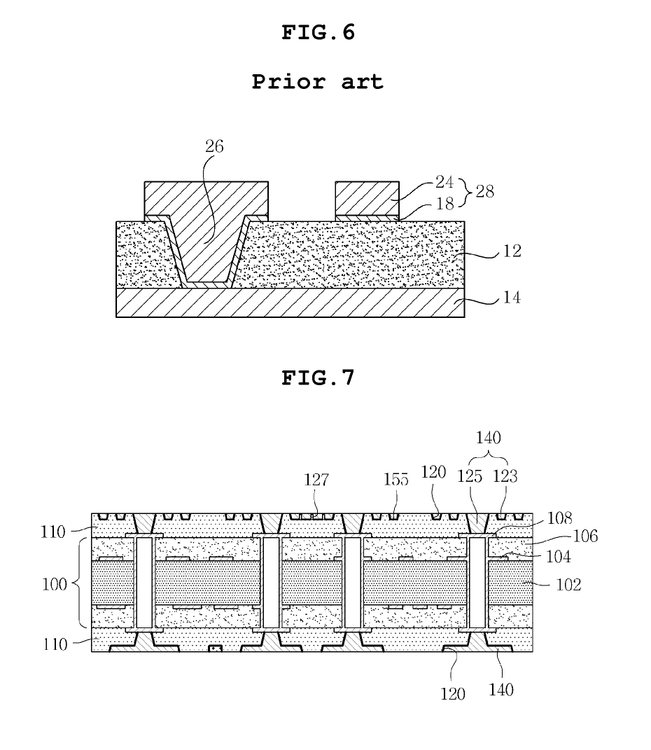

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 7 is a sectional view showing a printed circuit board according to a first embodiment of the present invention. Hereinafter, the printed circuit board according to the first embodiment of the present invention will be described with reference to FIG. 7.

As shown in FIG. 7, the printed circuit board according to this embodiment includes a base substrate 100, insulation layers 110 which are formed on both sides of the base substrate 100 and in which trenches 120 are formed, and circuit layers 140 including circuit patterns 123 and vias 125 formed in the trenches 120 using a plating process.

The base substrate 100 has a structure in which inner insulation layers 106, each having an inner circuit layer 108 formed on one side thereof, are formed on both sides of a core insulation layer 102 having core circuit layers 104 formed on both sides thereof, and the inner circuit layers 108 formed on the respective inner insulation layers 106 are connected to each other through inner vias passing through the core insulation layer 102 and the inner insulation layers 106. Here, the base substrate 100 shown in FIG. 7 is an example, and various types of base substrates may be used as the base substrate.

The insulation layers 110 are formed on both sides of the base substrate 100, and are formed therein with trenches 120 for forming circuit patterns 123 and vias 125. The trenches 120 may be formed in their entirety by engraving the insulation layers 110 in intaglio, and, preferably, may be formed therein with protrusions 127 by partially removing the insulation layers 110 engraved in intaglio. The protrusions 127 serve to allow the trenches 120 to be plated in uniform thicknesses by dividing large trenches into small trenches.

The circuit layers 140 include a circuit pattern 123 and vias 125, and are formed in the trenches 120 by a plating process. In this case, the circuit layers 140 are buried in the insulation layers 110 because they are formed in the trenches by a plating process.

According to the printed circuit board of this embodiment, since the circuit layers 140 are buried in the insulation layers 110, an undercut phenomenon does not occur at the lower ends of the circuit patterns in distinction to circuit layers formed using a conventional semi-additive process, thus easily realizing fine circuits. Further, according to the printed circuit board of this embodiment, the circuit layers 140 can be simultaneously formed using the trenches 120, thus simplifying the manufacturing process thereof.

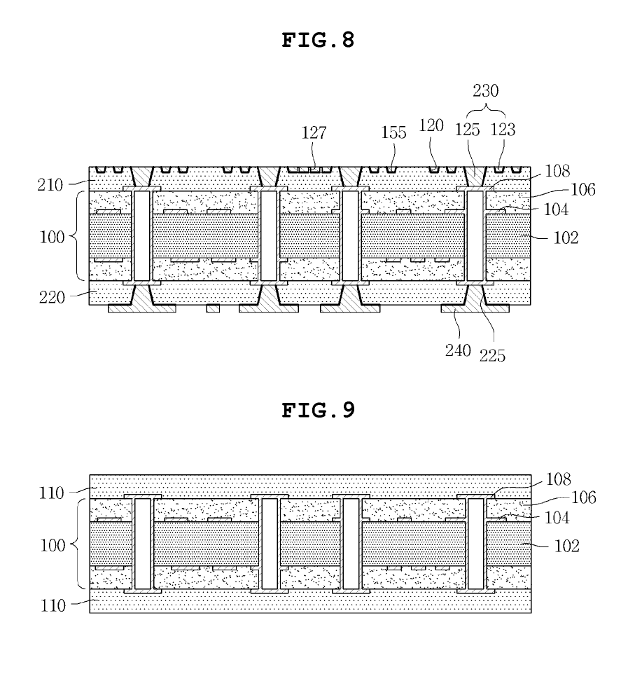

FIG. 8 is a sectional view showing a printed circuit board according to a second embodiment of the present invention. Hereinafter, the printed circuit board according to the second embodiment of the present invention will be described with reference to FIG. 8.

As shown in FIG. 8, the printed circuit board according to this embodiment includes a base substrate 100, a first insulation layer 210 which is formed on one side of the base substrate 100 and in which trenches 120 are formed, a second insulation layer 220 which is formed on the other side of the base substrate 100 and in which viaholes 225 are formed, a first circuit layer 230 including circuit patterns 123 and vias 125 formed in the trenches 120 formed in the first insulation layer 210 using a plating process, and a second circuit layer 240 including vias formed in the second insulation layer 220.

That is, in this embodiment, the base substrate 100 is provided on one side thereof with the first circuit layer 230 buried in the first insulation layer 210 using the trenches having the same structure as that of the trenches of the first embodiment, and is provided on the other side thereof with the second circuit layer 240 including protruded circuit patterns formed using a general circuit pattern forming process such as a subtractive process or a semi-additive process. Since the second embodiment is the same as the first embodiment except for this, the redundant description of the second embodiment will be omitted.

According to the printed circuit board of this embodiment, a high quality and high reliability fine circuit can be formed on one side thereof using the trenches 120, and a relatively price-competitive circuit layer can be formed on the other side thereof using a subtractive process or a semi-additive process, thus reducing the manufacturing cost thereof. That is, the printed circuit board of this embodiment is useful when a fine circuit is selectively formed on one side of a printed circuit board. Further, according to the printed circuit board of this embodiment, the circuit layers 230 and 240 can be simultaneously formed on both sides thereof using both trenches and a subtractive or semi-additive process, thus simplifying the manufacturing process thereof.

FIGS. 9 to 12 are sectional views showing a method of manufacturing the printed circuit board according to the first embodiment of the present invention. Hereinafter, the method of manufacturing the printed circuit board according to the first embodiment of the present invention will be described with reference to FIGS. 9 to 12.

First, as shown in FIG. 9, insulation layers 110 are formed on both sides of a base substrate 100. Here, the base substrate 100, shown in FIG. 9, has a structure in which inner insulation layers 106, each having an inner circuit layer 108 formed on one side thereof, are formed on both sides of a core insulation layer 102 having core circuit layers 104 formed on both sides thereof, and the inner circuit layers 108 formed on the respective inner insulation layers 106 are connected to each other through inner vias passing through the core insulation layer 102 and the inner insulation layers 106. However, the base substrate 100 shown in FIG. 7 is an example. For example, a single-layered insulating member may be used as the base substrate 100. In this case, the insulation layers 110 may not be additionally formed on both sides of the base substrate 100.

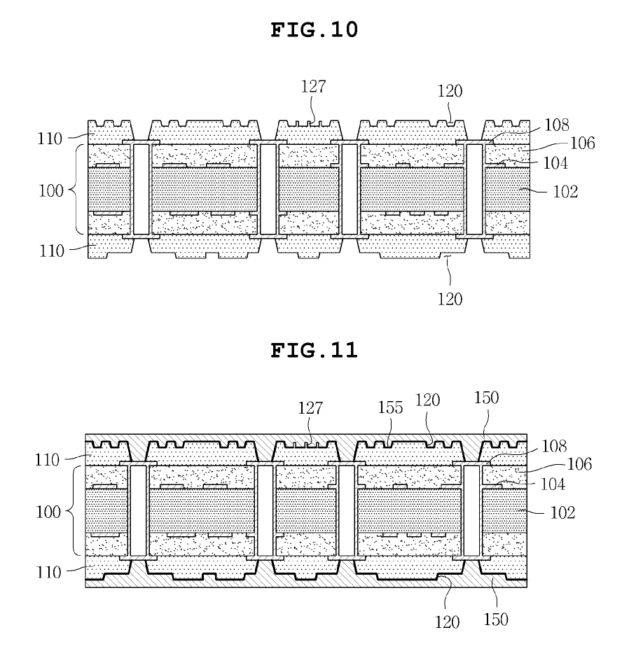

Subsequently, as shown in FIG. 10, trenches 120 are formed in the insulation layers 110. In this case, protrusions 127 may be locally formed in large trenches 120 by partially removing the insulation layers 110 engraved in intaglio such that a plating layer 150 can be formed on the insulation layer 110 in a uniform thickness in subsequent processes by dividing large trenches into small trenches.

Here, the trenches 120 are not particularly limited as long as they are well known in the related art, and may be formed using an imprint process or a laser process (for example, neodymium-doped yttrium aluminum garnet (Nd-YAG) laser, CO₂ laser, or pulse UV (ultra-violet) excimer laser).

Subsequently, as shown in FIG. 11, plating layers 150 are formed on the insulation layers 110 including the inner portions of the trenches 120 by a plating process. The two insulation layers 110 formed on both sides of the base substrate 100 may be simultaneously plated to simplify the manufacturing process of a printed circuit board. Specifically, electroless plating layers 155 are formed on the insulation layers 110 including the trenches 120 by electroless plating, and then the electroless plating layers 155 are formed into the plating layers 150 by electrolytic plating.

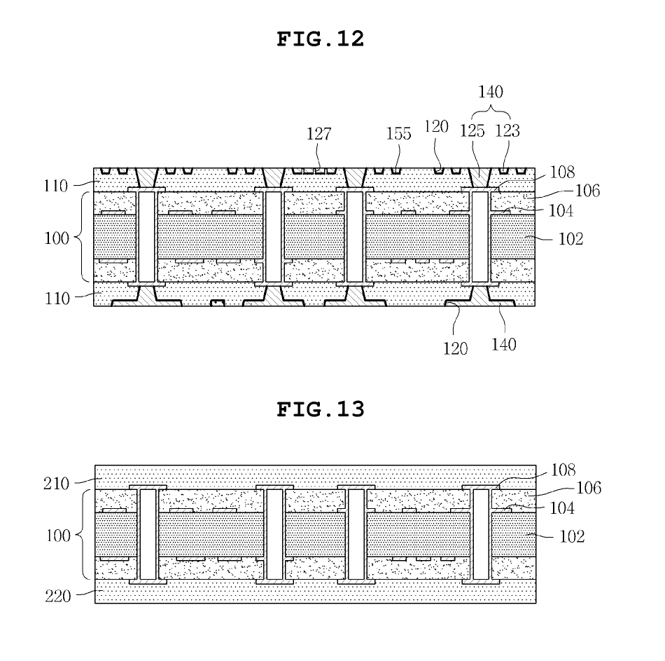

Subsequently, as shown in FIG. 12, circuit layers 140 are formed by removing the plating layers 150 excessively formed on the insulating layers 110. In the formation of the above plating layers 150, the plating layers 150 cannot function as circuit patterns 123 because they are excessively formed on the insulation layers 110. For this reason, the excessively formed plating layers 150 must be removed. The excessively formed plating layers 150 may be removed using any one selected from among mechanical grinding, chemical grinding, chemi-mechanical grinding, etching, and combinations thereof. The processes of removing the excessively formed plating layers 150 may be simultaneously performed on the two insulation layers 110 formed on both sides of the base substrate 100 to simplify the manufacturing process of a printed circuit board.

FIGS. 13 to 19 are sectional views showing a method of manufacturing the printed circuit board according to the second embodiment of the present invention. Hereinafter, the method of manufacturing the printed circuit board according to the second embodiment of the present invention will be described with reference to FIGS. 13 to 19.

First, as shown in FIG. 13, a first insulation layer 210 is formed on one side of a base substrate 100, and a second insulation layer 220 is formed on the other side of the base substrate 100. In this embodiment, the base substrate is the same as that of the above first embodiment, and the insulation layers are basically the same as those of the above first embodiment although the insulation layers are classified into the first insulation layer 210 and the second insulation layer 220. Here, the reason for classifying the insulation layers into the first insulation layer 210 and the second insulation layer 220 is to distinguish a constituent from other constituents.

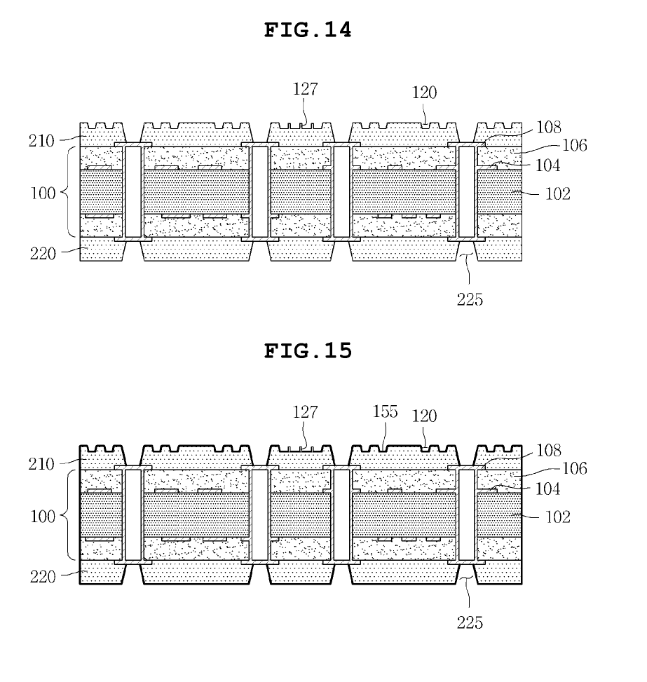

Subsequently, as shown in FIG. 14, trenches 120 are formed in the first insulation layer 210, and viaholes 225 are formed in the second insulation layer 220. In this case, protrusions 127 may be formed in large trenches 120 by partially removing the first insulation layer 210 engraved in intaglio such that a plating layer 250 can be formed on the first insulation layer 210 in uniform thickness in subsequent processes by dividing the large trenches into small trenches.

As in the first embodiment, the trenches 120 are formed in the first insulation layer 210 using an imprint process or a laser process (for example, neodymium-doped yttrium aluminum garnet (Nd-YAG) laser, CO₂ laser, or pulse UV (ultra-violet) excimer laser). Further, the viaholes 225 are formed in the second insulation layer 220 using YAG laser or CO₂ laser.

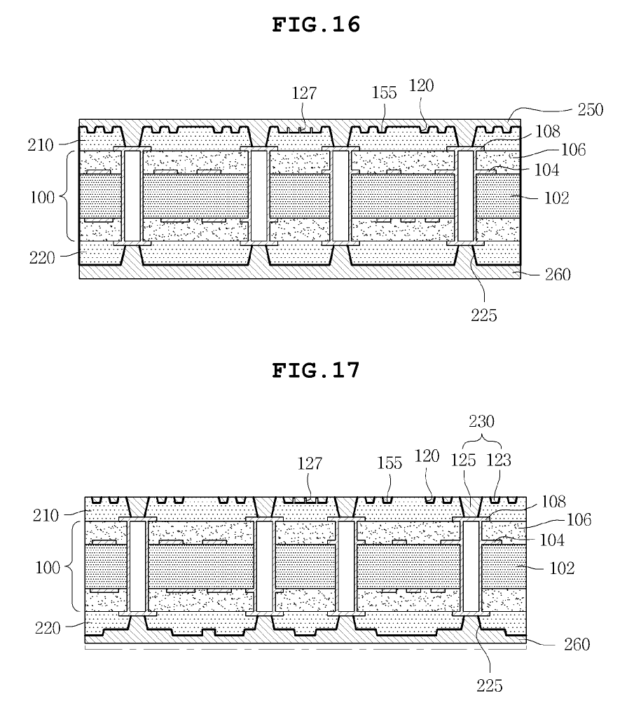

Subsequently, as shown in FIGS. 15 and 16, an electroless plating layer 155 is formed on the first insulation layers 210 including the trenches 120 by electroless plating and then the electroless plating layer 155 is formed into a first plating layer 250 by electrolytic plating, and an electroless plating layer 155 is formed on the second insulation layer 220 including the viaholes 225 by electroless plating and then the electroless plating layer 155 is formed into a second plating layer 260 by electrolytic plating. In this case, the first insulation layer 210 and the second insulation layer 220 may be respectively plated, but, as shown in FIGS. 15 and 16, may be simultaneously electroless-plated and then electrolytic-plated to simplify the manufacturing process of a printed circuit board.

Plating includes electroless plating and electrolytic plating. First, the electroless plating layers 155 are formed using electroless plating, and are then electrolytic-plated, so the first plating layer 250 is formed on the first insulation layer 210, and the second plating layer 260 is formed on the second insulation layer 220. Here, the first plating layer 250 and the second plating layer 260 may have thicknesses different from each other in consideration of subsequent processes for removing the first plating layer 250 and etching the second plating layer 260.

Subsequently, as shown in FIG. 17, a first circuit layer 230 is formed by removing the first plating layer 250 excessively formed on the first insulation layer 210. In the formation of the above first plating layer 250, the first plating layer 250 cannot function as a circuit pattern 123 because it is excessively formed on the first insulation layers 210. For this reason, the excessively formed first plating layer 250 must be removed. The excessively formed first plating layers 250 may be removed using any one selected from among mechanical grinding, chemical grinding, chemi-mechanical grinding, etching and combinations thereof, to form the first circuit layer 230.

Further, when the excessively formed first plating layer 250 is removed using etching, the second plating layer 260 may also be removed to a predetermined thickness using etching. In this case, the thickness of the etched second plating layer 260 finally becomes the thickness of a second circuit layer 240. That is, the second plating layer 260 is also etched when the second plating layer 250 is etched, and thus the thickness of a second circuit layer 240 which will be formed in subsequent processes can be determined

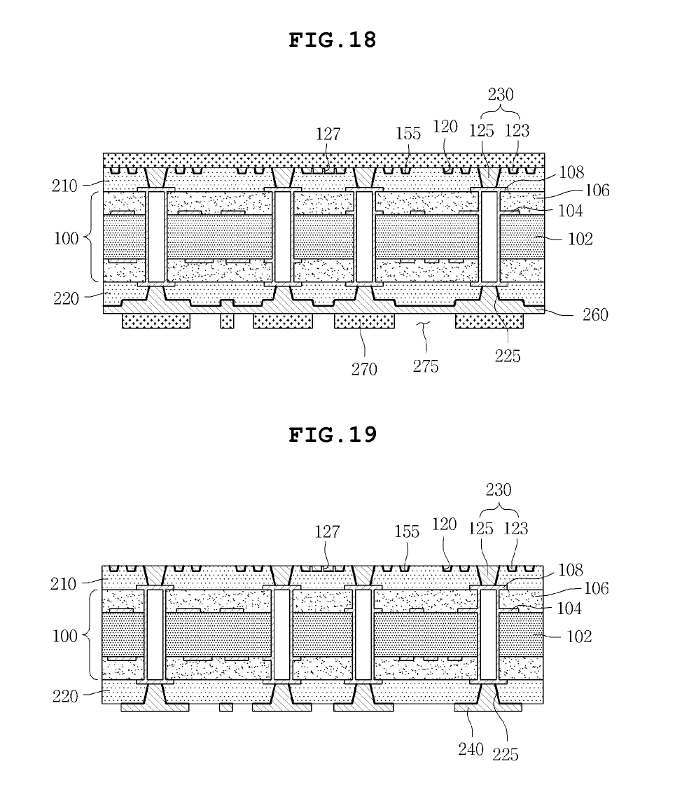

Subsequently, as shown in FIG. 18, a etching resist 270 is applied on the second plating layer 260, and then openings 275 for forming a circuit are formed in the etching resist 270. Here, a photosensitive material, such as a dry film, may be used as the etching resist 270, and the openings for forming a circuit may be formed by exposure or development. Meanwhile, in subsequent processes, a second circuit layer 240 is formed by etching. In this case, in order to prevent the previously-formed first circuit layer 230 from being damaged by etching, the etching resist 270 may be entirely applied on the first insulation layer 210.

Subsequently, as shown in FIG. 19, the second plating layer 260 exposed by the openings 275 for forming a circuit is removed by etching, and then the etching resist 270 is removed to form a second circuit layer 240. Specifically, only the second plating layer 260 exposed by the openings 275 for forming a circuit is selectively etched to realize a circuit pattern, and the etching resist 270 is removed using a stripping agent such as iron chloride, copper chloride or the like, to complete the second circuit layer 240.

According to the method of manufacturing a printed circuit board of this embodiment, the circuit layers 230 and 240 can be simultaneously formed by forming the circuit layer 230 using the trenches 120 and forming the circuit layer 240 using a subtractive process, thus increasing the efficiency of the manufacturing process of a printed circuit board.

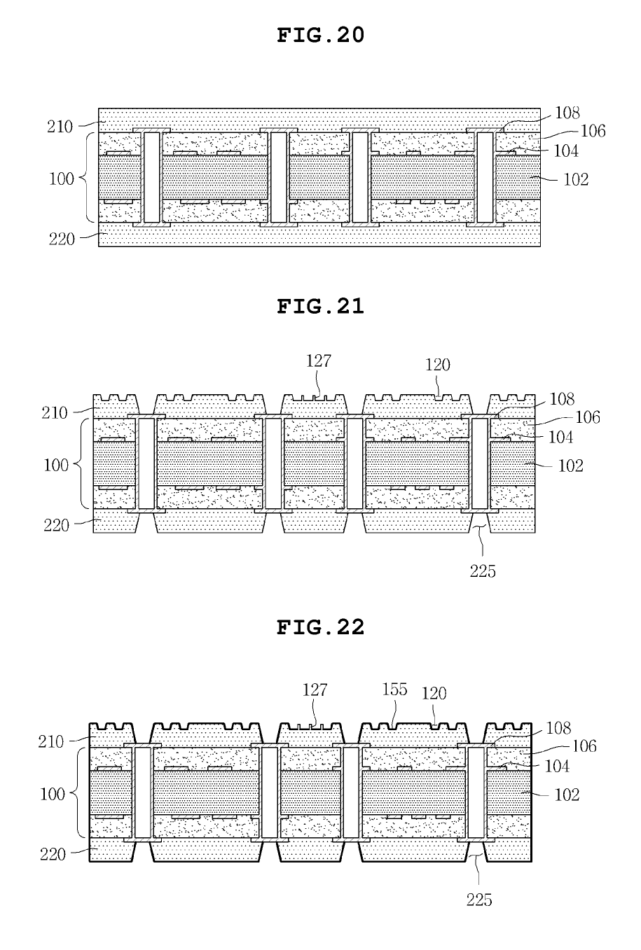

FIGS. 20 to 27 are sectional views showing a method of manufacturing the printed circuit board according to the third embodiment of the present invention. Hereinafter, the method of manufacturing the printed circuit board according to the third embodiment of the present invention will be described with reference to FIGS. 20 to 27.

First, as shown in FIGS. 20 and 21, a process of forming a first insulation layer 210 on one side of a base substrate 100 and forming a second insulation layer 220 on the other side thereof and a process of forming trenches 120 in the first insulation layer 210 and forming viaholes 225 in the second insulation layer 220 are the same as those of the above-mentioned second embodiment. Therefore, detailed descriptions of these processes will be omitted.

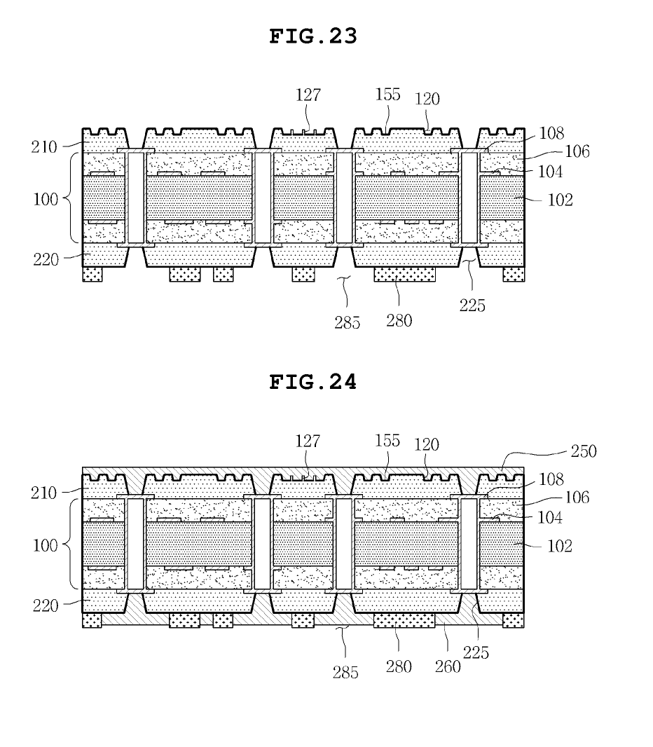

Subsequently, as shown in FIGS. 22 and 23, an electroless plating layer 155 is formed on the first insulation layers 210 including the trenches 120, and an electroless plating layer 155 is formed on the second insulation layer 220 including the viaholes 225, and then a plating resist 280 is applied on the second insulation layer 220 and then openings 285 for forming a circuit are formed in the plating resist 280. In this case, the first insulation layer 210 and the second insulation layer 220 may be respectively electroless-plated, but, as shown in FIGS. 22 and 23, may be simultaneously electroless-plated to increase the efficiency of the manufacturing process of a printed circuit board. Meanwhile, the plating resist 280 is applied on the second insulation layer 220, and then the openings 285 for forming a circuit are formed in the plating resist 280 using exposure or development. A second plating layer 260 is formed in the openings 285 for forming a circuit in subsequent processes.

Subsequently, as shown in FIG. 24, a first plating layer 250 is formed on the first insulation layer 210 including the trenches 120 by electrolytic-plating the electroless plating layer 155, and a second plating layer 260 is formed in the openings 285 for forming a circuit. In this case, the first insulation layer 210 and the openings 285 for forming a circuit may be respectively electrolytic-plated, but, as shown in FIGS. 22 and 23, may be simultaneously electrolytic-plated to increase the efficiency of the manufacturing process of a printed circuit board. Further, the first plating layer 250 and the second plating layer 260 may have different thicknesses from each other in consideration of a subsequent process for removing the first plating layer 250.

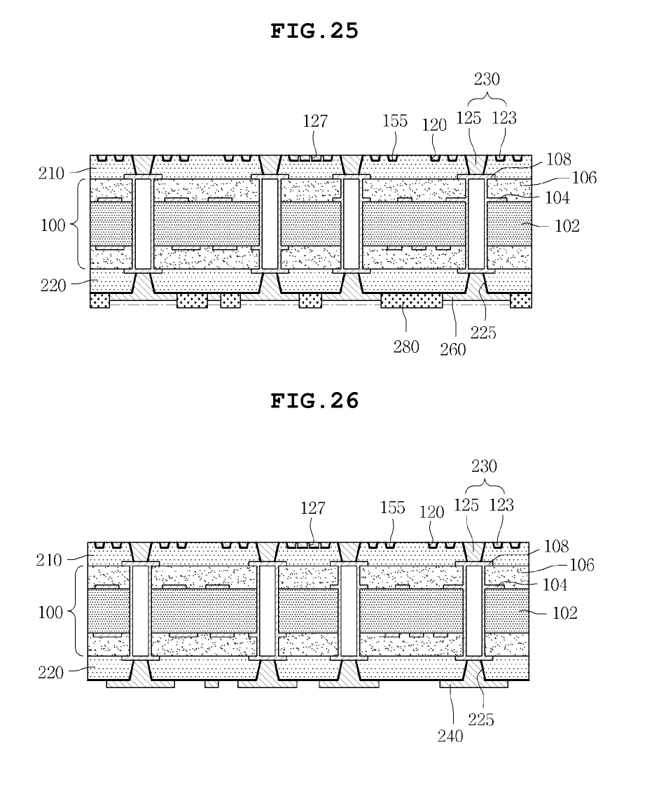

Subsequently, as shown in FIG. 25, a first circuit layer 230 is formed by removing the first plating layer 250 excessively formed on the first insulation layer 210. In the formation of the above first plating layer 250, the first plating layer 250 cannot function as a circuit pattern 123 because it is excessively formed on the first insulation layer 210. For this reason, the excessively formed first plating layer 250 must be removed. The excessively formed first plating layer 250 may be removed using any one selected from among mechanical grinding, chemical grinding, chemi-mechanical grinding, etching and combinations thereof, thus forming the first circuit layer 230.

Further, when the excessively formed first plating layer 250 is removed using etching, the second plating layer 260 may also be removed to a predetermined thickness using etching. In this case, the thickness of the etched second plating layer 260 finally becomes the thickness of a second circuit layer 240. That is, the second plating layer 260 is also etched when the second plating layer 250 is etched, and thus the thickness of a second circuit layer 240 which will be formed in subsequent processes can be determined

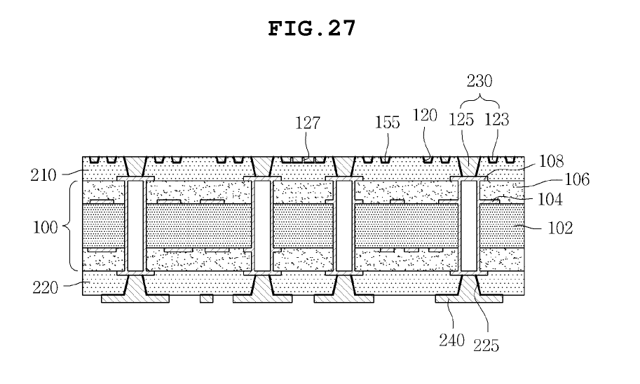

Subsequently, as shown in FIGS. 26 and 27, a second circuit layer 240 is formed by stripping the plating resist 280 and then removing the electroless plating layer 155. Here, the electroless plating layer 155 may be selectively removed by removing only the portion thereof on which the second plating layer 260 is not formed, and may be generally removed using flash etching or quick etching.

According to the method of manufacturing a printed circuit board of this embodiment, the circuit layers 230 and 240 can be simultaneously formed by forming the circuit layer 230 using the trenches 120 and forming the circuit layer 240 using a semi-additive process, thus increasing the efficiency of the manufacturing process of a printed circuit board.

As described above, according to the present invention, trenches are formed at both sides of a base substrate, so that circuit patterns can be simultaneously formed at both sides thereof, thereby simplifying a manufacturing process and realizing fine circuit patterns.

Further, according to the present invention, circuit layers are simultaneously formed on both sides of a base substrate by forming a circuit layer on one side thereof using trenches and forming a circuit layer on the other side thereof using a subtractive process or a semi-additive process, thus simplifying a manufacturing process and reducing a manufacturing cost.

Furthermore, according to the present invention, protrusions are formed in trenches, so that the trenches are divided into small trenches, thereby improving plating deviation.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A printed circuit board, comprising:
a base substrate;
insulation layers which are formed on both sides of the base substrate and in which trenches are formed; and
circuit layers including circuit patterns and vias formed in the trenches using a plating process.

2. The printed circuit board according to claim 1, wherein protrusions are formed in the trenches.

3. A printed circuit board, comprising:
a base substrate;
a first insulation layer which is formed on one side of the base substrate and in which trenches are formed;
a second insulation layer which is formed on the other side of the base substrate and in which viaholes are formed;
a first circuit layer including circuit patterns and vias formed in the trenches formed in the first insulation layer using a plating process; and
a second circuit layer including vias formed in the second insulation layer.

4. The printed circuit board according to claim 3, wherein protrusions are formed in the trenches.

5. A method of manufacturing a printed circuit board, comprising:
forming insulation layers on both sides of a base substrate;
forming trenches in the insulation layers;
forming plating layers on the insulation layers including the trenches by a plating process; and
forming circuit layers by removing the plating layers excessively formed on the insulating layers.

6. The method of manufacturing a printed circuit board according to claim 5, wherein, in the forming of the plating layers, the plating layers are formed by forming electroless plating layers on the insulation layers including the trenches and then electrolytic-plating the electroless plating layers.

7. The method of manufacturing a printed circuit board according to claim 5, wherein, in the forming of the circuit layers, the circuit layers are formed by etching the excessively formed plating layers.

8. The method of manufacturing a printed circuit board according to claim 5, wherein, in the forming of the circuit layers, the circuit layers are formed by grinding the excessively formed plating layers.

9. A method of manufacturing a printed circuit board, comprising:
forming a first insulation layer on one side of a base substrate, and forming a second insulation layer on the other side of the base substrate;
forming trenches in the first insulation layer, and forming viaholes in the second insulation layer; and
forming a first circuit layer in the trenches formed in the first insulation layer by a plating process, and forming a second circuit layer including vias on the second insulation layer by a plating process.

10. The method of manufacturing a printed circuit board according to claim 9, wherein the forming of the first circuit layer and the second circuit layer comprises:
forming an electroless plating layer on the first insulation layer including the trenches and then electrolytic-plating the electroless plating layer to form a first plating layer, and forming an electroless plating layer on the second insulation layer including the vias and then electrolytic-plating the electroless plating layer to form a second plating layer;
removing the first plating layer excessively formed on the first insulation layer to form the first circuit layer;
applying a etching resist onto the second plating layer and then forming openings for forming a circuit in the etching resist; and
removing the second plating layer exposed through the openings for forming a circuit by etching and then removing the etching resist to form the second circuit layer.

11. The method of manufacturing a printed circuit board according to claim 10, wherein, in the forming of the first plating layer and the second plating layer, the thickness of the first plating layer is different from that of the second plating layer.

12. The method of manufacturing a printed circuit board according to claim 10, wherein, in the forming of the first circuit layer, the first plating layer excessively formed on the first insulation layer is removed by etching.

13. The method of manufacturing a printed circuit board according to claim 12, wherein, in the forming of the first circuit layer, when the first plating layer is removed by etching, the second plating layer is removed to a predetermined thickness by etching.

14. The method of manufacturing a printed circuit board according to claim 10, wherein, in the forming of the first circuit layer, the first plating layer excessively formed on the first insulation layer is removed by grinding.

15. The method of manufacturing a printed circuit board according to claim 9, wherein the forming of the first circuit layer and the second circuit layer comprises:
forming an electroless plating layer on the first insulation layer including the trenches, and forming an electroless plating layer on the second insulation layer including the vias, and then applying a plating resist on the second insulation layer and then forming openings for forming a circuit in the plating resist;
electrolytic-plating the electroless plating layer to form a first plating layer on the first insulation layer including the trenches and to form a second plating layer in the openings for a circuit;
removing the first plating layer excessively formed on the first insulation layer to form the first circuit layer; and
stripping the plating resist and then removing the electroless plating layer to form the second circuit layer.

16. The method of manufacturing a printed circuit board according to claim 15, wherein, in the forming of the first plating layer and the second plating layer, the thickness of the first plating layer is different from that of the second plating layer.

17. The method of manufacturing a printed circuit board according to claim 15, wherein, in the forming of the first circuit layer, the first plating layer excessively formed on the first insulation layer is removed by etching.

18. The method of manufacturing a printed circuit board according to claim 17, wherein, in the forming of the first circuit layer, when the first plating layer is removed by etching, the second plating layer is removed to a predetermined thickness by etching.

19. The method of manufacturing a printed circuit board according to claim 15, wherein, in the forming of the first circuit layer, the first plating layer excessively formed on the first insulation layer is removed by grinding.
